(19) United States
(12) Patent Application Publication
(10) Pub. No.: US 2026/0214936 A1
(43) Pub. Date: Jul. 23, 2026

(54) TRENCH-TYPE MOSFET AND MANUFACTURING METHOD THEREOF

(71) Applicant: Winbond Electronics Corp., Taichung City (TW)

(72) Inventors: Shuen-Hsiang Ke, Taichung City (TW); Chia-Wen Chiang, Taichung City (TW); Huang-Nan Chen, Taichung City (TW)

(73) Assignee: Winbond Electronics Corp., Taichung City (TW)

(21) Appl. No.: 19/034,570

(22) Filed: Jan. 23, 2025

(51) Int. Cl. H10D 30/66; H10D 30/01; H10D 62/17; H10D 64/27

(52) U.S. Cl. CPC H10D 30/668; H10D 30/0297; H10D 62/393; H10D 64/513

(57) ABSTRACT

Disclosed is trench-type MOSFET including a substrate and a buried gate structure. The substrate includes a body region, a body contact region formed on the body region, and a source region adjacent to the body contact region and formed on the body region, wherein conductivity type of the source region is different from the conductivity type or the doping concentration of the body contact region. The buried gate structure is formed in the body region and at a side of the source region and the body contact region, wherein the substrate has a recess formed on the source region, such that the surface of the source region located at the bottom of the recess is lower than the top surface of the body contact region. A manufacturing method of a trench-type MOSFET is also disclosed.

### BACKGROUND

### Technical Field

The present disclosure relates to a semiconductor device and a manufacturing method thereof, and particularly relates to a trench-type MOSFET (Metal-Oxide-Semiconductor Field-Effect Transistor) and a manufacturing method thereof.

### Description of Related Art

Power semiconductors are specifically designed to process high-power voltages and currents, and are frequently employed in power converters, sensors, radio frequency components, automotive electronic components, and various other applications. In comparison to planar power semiconductors, trench-type MOSFET is more advantageous for use in portable or miniature devices. Currently, the technology for trench-type MOSFET is continually progressing towards device miniaturization. However, it has been increasingly challenging to further reduce the source width using known trench-type MOSFET manufacturing processes. Moreover, in order to remove the anti-reflective layer after forming the source, complex masking steps are required to simultaneously protect the already-formed source. Furthermore, considering the demand for energy conservation, there is still room for making improvement for conventional trench-type MOSFET. Therefore, enhancing trench-type MOSFET and the manufacturing methods thereof remains one of the critical issues to be addressed at present.

### SUMMARY

The present disclosure provides a trench-type MOSFET (Metal-Oxide-Semiconductor Field-Effect Transistor) and a manufacturing method thereof, which is favorable for miniaturization of the source width, and does not require the execution of the aforementioned complex masking steps.

The trench-type MOSFET of the present disclosure includes a substrate and a buried gate structure. The substrate includes a body region, a body contact region formed on the body region, and a source region formed on the body region and located adjacent to the body contact region. A conductivity type of the source region is different from a conductivity type of the body contact region. The buried gate structure is formed in the body region and located at one side of the body contact region and the source region. The substrate has a recess formed on the source region, such that the surface of the source region at the bottom of the recess is lower than the top surface of the body contact region.

The manufacturing method of the trench-type MOSFET of the present disclosure includes the following steps: forming a body region in the substrate; forming a body contact region in the body region; forming a source region on the body region and adjacent to the body contact region, wherein a conductivity type of the source region is different from a conductivity type of the body contact region; forming a recess on the source region, such that the surface of the source region at the bottom of the recess is lower than the top surface of the body contact region; forming a buried gate structure in the body region, wherein the buried gate structure is located at one side of the body contact region and the source region.

Based on the above, in the trench-type MOSFET of the present disclosure, by forming a recess on the source region, it is possible to make the top surface of the source region to be lower than the top surface of the body contact region. Through this design, the trench-type MOSFET provided by the present disclosure may have a relatively low on-resistance, thereby reducing the power consumption of the trench-type MOSFET.

### BRIEF DESCRIPTION OF THE DRAWINGS

FIG. 1 is a flow diagram illustrating a manufacturing method of a trench-type MOSFET according to an embodiment of the present disclosure.

FIG. 2A is a partial perspective diagram illustrating a trench-type MOSFET according to an embodiment of the present disclosure.

FIG. 2B is a partial cross-sectional diagram taken along the section line A-A' in FIG. 2A.

FIG. 2C is a partial cross-sectional diagram taken along the section line B-B' in FIG. 2A.

FIG. 2D is a partial cross-sectional diagram taken along the section line C-C' in FIG. 2A.

FIG. 3 is a cross-sectional diagram illustrating an intermediate manufacturing process of a buried gate structure in a trench-type MOSFET according to an embodiment of the present disclosure.

FIG. 4A to FIG. 4F are cross-sectional diagrams illustrating a recess formed on the source region according to various embodiments of the present disclosure.

FIG. 5A is a partial perspective diagram illustrating a trench-type MOSFET according to another embodiment of the present disclosure.

FIG. 5B is a partial cross-sectional diagram taken along the section line D-D' in FIG. 5A.

FIG. 5C is a partial cross-sectional diagram taken along the section line B-B' in FIG. 5A.

FIG. 5D is a partial cross-sectional diagram taken along the section line C-C' in FIG. 5A.

FIG. 6A is a partial perspective diagram illustrating a trench-type MOSFET according to yet another embodiment of the present disclosure.

FIG. 6B is a partial cross-sectional diagram taken along the section line A-A' in FIG. 6A.

FIG. 6C is a partial cross-sectional diagram taken along the section line E-E' in FIG. 6A.

### DESCRIPTION OF THE EMBODIMENTS

In the following embodiments, the first conductive type is N-type, and the second conductive type is P-type; however, the present disclosure is not limited thereto. In other embodiments, the first conductive type may be P-type, and the second conductive type may be N-type. P-type dopants exemplify boron, and N-type dopants exemplify phosphorus or arsenic. Unless otherwise defined, all terms used herein have the same meanings as commonly understood by those of ordinary skill in the field to which this disclosure pertains. Furthermore, the illustrative figures herein are only used to illustrate parts of the embodiments of the present disclosure.

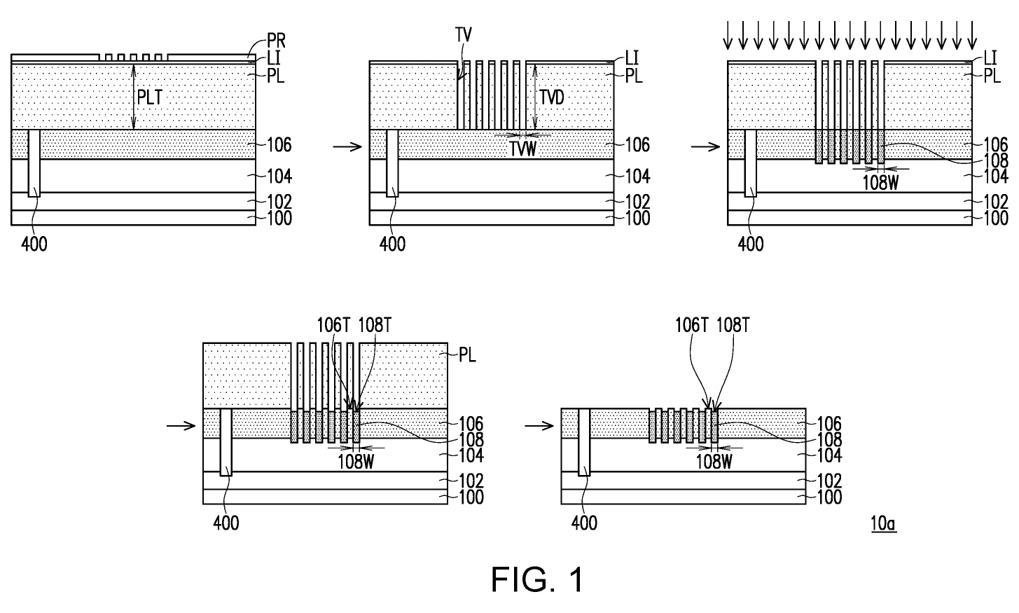

The following description with reference to FIG. 1 to FIG. 3 explains a trench-type MOSFET (Metal-Oxide-Semiconductor Field-Effect Transistor) 10a and a manufacturing method thereof according to an embodiment of the present disclosure.

Please refer to FIG. 1, a body region 104 is formed in the substrate 100. The substrate 100 may be a suitable semiconductor material. For example, the material of the substrate 100 may include silicon (Si), germanium (Ge), gallium arsenide (GaAs), silicon germanium (SiGe), other suitable materials, or combinations of the above materials. The present disclosure is not limited thereto.

In some embodiments, before forming the body region 104, a drift region 102 may be formed in the substrate 100. In other words, the body region 104 is located on the drift region 102. The drift region 102 may be formed through a metal organic chemical vapor deposition (MOCVD) process, but the present disclosure is not limited thereto. In other embodiments, the drift region 102 may be formed through a hydride vapor phase epitaxy (HVPE) process or a molecular beam epitaxy (MBE) process. In some embodiments, the drift region 102 has a first conductive type. For example, the drift region 102 may be an N-type epitaxial layer, but the present disclosure is not limited thereto. In other embodiments, the drift region 102 may have a second conductive type.

In some embodiments, the body region 104 may be formed in the drift region 102 through an ion implantation process, but the present disclosure is not limited thereto. In other embodiments, the body region 104 may be formed on the drift region 102 through a suitable epitaxial growth process. In some embodiments, the body region 104 may have a different conductive type from the drift region 102.

Subsequently, a body contact region 106 may be formed in the body region 104, for example, through an ion implantation process. In some embodiments, the body contact region 106 has the same conductive type as the body region 104, and the body contact region 106 has a higher doping concentration.

Subsequently, a source region 108 is formed on the body region 104 and located adjacent to the body contact region 106. The top surface 108T of the source region 108 of the present disclosure is lower than the top surface 106T of the body contact region 106. Forming the source region 108 may include the following steps.

First, an implantation blocking layer PL, a hard mask layer LI, and a patterned photoresist layer PR are formed in sequence on the body region 104. In some embodiments, the implantation blocking layer PL may be formed on the drift region 102 through a coating process. The material of the implantation blocking layer PL may include, for example, suitable organic materials. In some embodiments, the thickness PLT of the implantation blocking layer PL may be greater than the thickness of the patterned photoresist layer PR, thereby providing a good implantation blocking effect and favorable to improving the accuracy of patterning.

In some embodiments, the hard mask layer LI may be formed on the implantation blocking layer PL through a chemical vapor deposition process, a thermal oxidation process, or a combination thereof, but the present disclosure is not limited thereto. The material of the hard mask layer LI may include oxide, for example, silicon oxide. The thickness of the hard mask layer LI may be smaller than the thickness of the implantation blocking layer PL and the thickness of the patterned photoresist layer PR.

In some embodiments, the patterned photoresist layer PR may be formed on the hard mask layer LI through a coating process, but the present disclosure is not limited thereto. The material of the patterned photoresist layer PR may be different from that of the implantation blocking layer PL.

Subsequently, the hard mask layer LI and the implantation blocking layer PL may be patterned using the patterned photoresist layer PR as a mask to form multiple through holes TV in the implantation blocking layer PL, so as to expose the surface of the body region 104 where the source region 108 is predetermined to be formed. Specifically, in this embodiment, the multiple through holes TV expose a position of the surface of the body contact region 106 predetermined to be replaced by the source region 108. However, in some embodiments that are not shown, since the body contact region 106 is formed after the formation of the source region 108, the multiple through holes TV expose a position of the surface of the body region 104 where the source region 108 is predetermined to be formed. In some embodiments, the aspect ratio of the through holes TV may be greater than or equal to 7, thereby favorable to process miniaturization.

Then, an ion implantation process is performed on the exposed surface of the body contact region 106 corresponding to the through holes TV of the implantation blocking layer PL to form the source region 108. In this embodiment, the width 108W of the source region 108 may not be greater than 200 nm. In this embodiment, the source region 108 has a conductive type different from that of the body contact region 106. In some other embodiments, the doping concentration of the source region 108 may be greater than the doping concentration of the body contact region 106. In some embodiments that are not shown, since the body contact region 106 is formed after the formation of the source region 108, the ion implantation process is performed on the exposed surface of the body region 104 corresponding to the through holes TV of the implantation blocking layer PL to form the source region 108.

According to this embodiment, by the implantation blocking layer PL having a thickness greater than the thickness of the patterned photoresist layer PR, it is possible to effectively block ion implantation from affecting the adjacent region (ex. the body contact region 106) during the formation of the source region 108, thereby favorable to more precisely controlling the width 108W of the source region 108. Furthermore, by the through holes TV with an aspect ratio greater than or equal to 7, the setting may be favorable to the miniaturization of the width 108W of the source region 108.

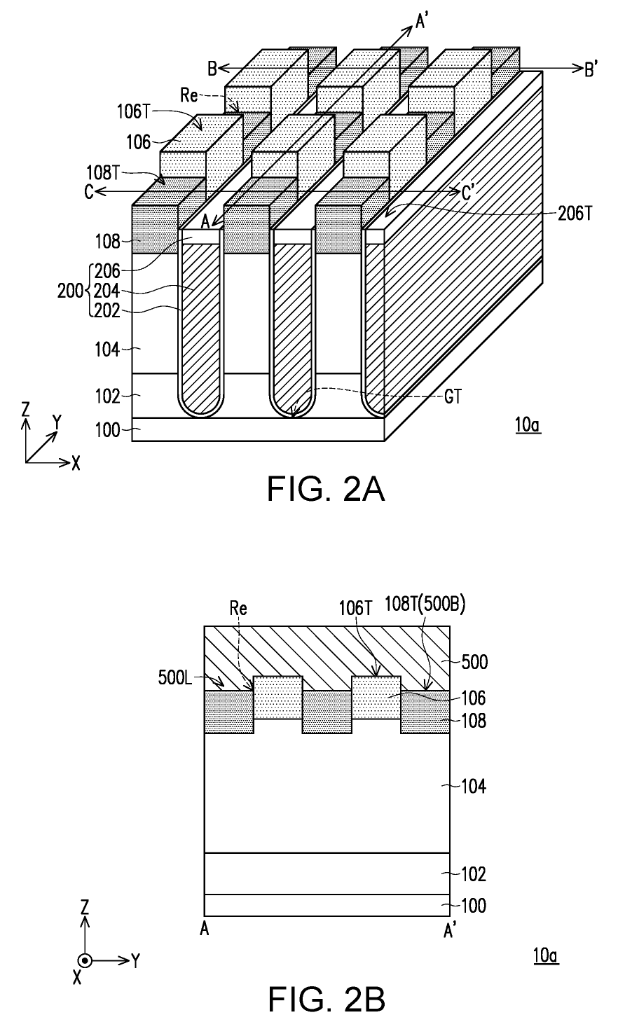

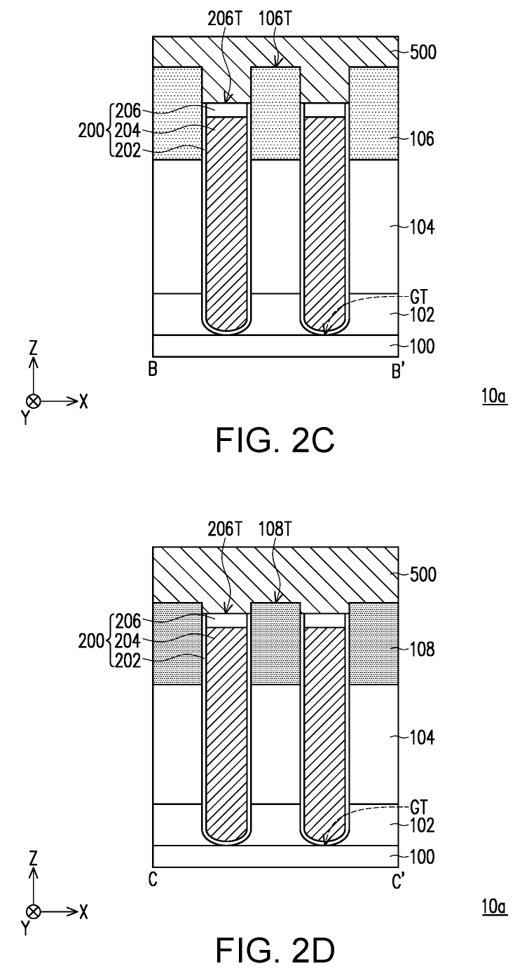

Subsequently, an etching process is performed to remove the hard mask layer LI and form a recess Re (labeled in FIG. 2A) on the source region 108.

In some embodiments, the hard mask layer LI may be removed by a dry etching process. For example, fluoride ion plasma may be used to remove the hard mask layer LI. It should be noted that during the removal of the hard mask layer LI, the part of the source region 108 exposed by the through holes TV is removed simultaneously. As a result, the top surface 108T of the source region 108 of the present disclosure is lower than the top surface 106T of the body contact region 106.

In a more favorable embodiment, by the implantation blocking layer PL with through holes TV having an aspect ratio greater than or equal to 7, and using fluoride ion plasma to perform the aforementioned etching process, it is possible to precisely control the depth of the recess Re formed on the source region 108, thereby favorable to improving yield.

Then, the implantation blocking layer PL is removed. In some embodiments, the implantation blocking layer PL may be removed through a stripping process. After removing the implantation blocking layer PL, a cleaning process may be performed to remove potentially remaining impurities.

In this embodiment, as shown in FIG. 2A, before forming the source region 108, for example, after forming the body contact region 106 and before forming the implantation blocking layer PL, a buried gate structure 200 may be formed in the body region 104, such that the buried gate structure 200 is located at one side of the body contact region 106 and the subsequently formed source region 108. The buried gate structure 200 may include a gate insulating layer 202, a buried gate electrode 204, and an insulating cap layer 206. In this embodiment, forming the buried gate structure 200 may include the following steps.

First, multiple gate trenches GT are formed in the body region 104. In some embodiments, the aspect ratio of the gate trenches GT may be at least 2.5, but the present disclosure is not limited thereto. In some embodiments, the gate trenches GT may penetrate through the body region 104 and extend into the drift region 102. In some embodiments, the bottom surface of the gate trenches GT may be located between the bottom surface of the body region 104 and the bottom surface of the drift region 102.

Subsequently, the gate insulating layer 202 is formed on the surface of the gate trenches GT. In some embodiments, the gate insulating layer 202 may be conformally formed through a chemical vapor deposition (CVD) process, a physical vapor deposition (PVD) process, an atomic layer deposition (ALD) process, a spin coating process, or thermal oxidation process. The material of the gate insulating layer 202 may include, for example, suitable dielectric materials. For instance, the material of the gate insulating layer 202 may include silicon oxide (SiO₂), silicon nitride (Si₃N₄), aluminum oxide (Al₂O₃), tantalum oxide (Ta₂O₅), titanium oxide (TiO₂), zinc oxide (ZnO₂), hafnium oxide (HfO₂), or combinations thereof.

Then, the buried gate electrode 204 is formed on the gate insulating layer 202. In some embodiments, the buried gate electrode 204 may be formed by forming a gate electrode material layer (not shown) first through a chemical vapor deposition process, a physical vapor deposition process, an atomic layer deposition process, or combinations thereof, followed by performing an etch-back process on the gate electrode material layer, but the present disclosure is not limited thereto. The material of the buried gate electrode 204 may include, for example, polysilicon, but the present disclosure is not limited thereto. In other embodiments, the material of the buried gate electrode 204 may include metal or metal alloy. For instance, the material of the buried gate electrode 204 may include copper (Cu), aluminum (Al), tungsten (W), nickel (Ni), cobalt (Co), or combinations thereof, but the present disclosure is not limited thereto.

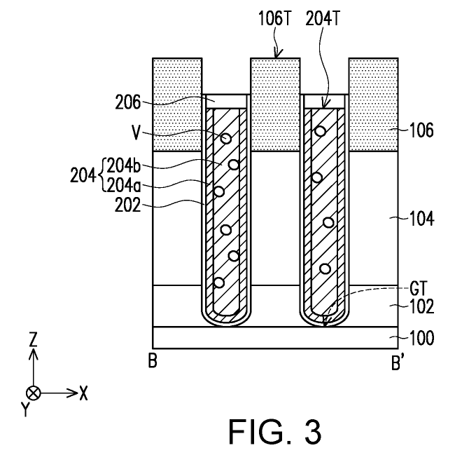

Specifically, referring to FIG. 3, in some embodiments, to further improve the yield and electrical performance of the trench-type MOSFET 10a, the buried gate electrode 204 may include a conformal gate layer 204a without voids and a gate filling layer 204b with a void V, and the void V is at least 10 nm away from the gate insulating layer 202. Specifically, the buried gate electrode 204 of this embodiment may be formed by the following steps. The conformal gate layer 204a without voids is formed on the gate insulating layer 202, a first annealing process is performed sequentially, then the oxide of the conformal gate layer 204a is removed, the gate filling layer 204b with the void V is formed, a second annealing process is performed, and the conformal gate layer 204a and the gate filling layer 204b are etched back, such that the top surface 204T of the buried gate electrode 204 is lower than the top surface 106T of the body contact region 106. In this way, it is possible to effectively prevent the void V from contacting the gate insulating layer 202, thereby averting issues such as current leakage, abnormal gate control (Vt shift), or reliability anomalies resulting from a shortened lifespan of the gate insulating layer 202.

Afterwards, an insulating cap layer 206 is formed on the buried gate electrode 204. The insulating cap layer 206 is formed, for example, in multiple gate trenches GT to cover the buried gate electrode 204. Accordingly, the insulating cap layer 206 and the gate insulating layer 202 may together wrap the buried gate electrode 204. The formation method and material of the insulating cap layer 206 may be the same as or similar to the formation method and material of the gate insulating layer 202, which will not be repeated here. In this embodiment, as shown in FIG. 2A, the surface 108T of the source region 108 exposed at the bottom of the recess Re is not lower than the top surface 206T of the insulating cap layer 206.

Additionally, in this embodiment, the manufacturing method of the trench-type MOSFET 10a may further include forming an isolating structure 400 in the drift region 102 to isolate the buried gate structure 200 from peripheral circuits (not shown), but the disclosure is not limited thereto. In some embodiments, the isolating structure 400 may include a shallow trench isolating structure. The material of the isolating structure 400 may be, for example, silicon oxide, silicon nitride, or a combination thereof.

As shown in FIG. 2B, in this embodiment, the manufacturing method of the trench-type MOSFET 10a may further include forming a source electrode 500 on the source region 108 and the body contact region 106, wherein the source electrode 500 is electrically connected to the source region 108 and the body contact region 106. The source electrode 500 may include multiple extension parts 500L filled in the recess Re, so that the bottom surface 500B of each extension part 500L is lower than the top surface 106T of the body contact region 106.

In some embodiments, the source electrode 500 may be formed through a CVD process, a PVD process, or an ALD process. The material of the source electrode 500 may include, for example, suitable metals or metal alloys. For instance, the material of the source electrode 500 may include copper (Cu), aluminum (Al), tungsten (W), nickel (Ni), cobalt (Co), or combinations thereof.

Additionally, in this embodiment, the manufacturing method of the trench-type MOSFET 10a may further include forming a drain electrode (not shown) on the surface of the substrate 100 away from the drift region 102.

In this embodiment, by forming through holes TV in the implantation blocking layer PL, a part of the source region 108 may also be removed during the process of removing the hard mask layer LI, so that the top surface 108T of the source region 108 is lower than the top surface 106T of the body contact region 106. Moreover, the source electrode 500 may include multiple extension parts 500L filled in the recess Re. In this way, it is favorable to the miniaturization of the source width, and there is no need to execute the complex masking steps described in the description of related art. Furthermore, the trench-type MOSFET 10a of this embodiment may have a relatively low on-resistance, which may reduce the power consumption of the trench-type MOSFET 10a.

The following will briefly introduce the trench-type MOSFET 10a of this embodiment with reference to FIG. 2A to FIG. 2D and FIG. 3. The remaining detailed content of the trench-type MOSFET 10a of this embodiment may be understood by referring to the above explanation, and will not be repeated here.

Please refer to FIG. 2A to FIG. 2D, the trench-type MOSFET 10a of this embodiment includes a substrate 100 and a buried gate structure 200.

The substrate 100, for example, has a first conductive type, which may be an N-type substrate, but the disclosure is not limited thereto. In this embodiment, the substrate 100 includes a body region 104, a body contact region 106, and a source region 108.

The body region 104 may be disposed in the substrate 100. In some embodiments, the body region 104 may have a second conductive type. For example, the body region 104 may include P-type dopants, but the disclosure is not limited thereto.

The body contact region 106 may be disposed on the body region 104, and has the second conductive type, for example. For instance, the body contact region 106 may include P-type dopants, but the disclosure is not limited thereto.

The source region 108 may be disposed on the body region 104 and located adjacent to the body contact region 106. In this embodiment, the source region 108 may have the first conductive type. For example, the source region 108 may include N-type dopants, but the disclosure is not limited thereto. In some other embodiments, the doping concentration of the source region 108 may be greater than the doping concentration of the body contact region 106. In this embodiment, the width 108W (labeled in FIG. 1) of the source region 108 may not be greater than 200 nm. In a more favorable embodiment, the width 108W of the source region 108 may be less than or equal to 150 nm.

More specifically, in this embodiment, the substrate 100 has a recess Re formed on the source region 108, such that the surface 108T of the source region 108 located at the bottom of the recess Re is lower than the top surface 106T of the body contact region 106, thereby the trench-type MOSFET 10a may have a relatively low on-resistance, which may reduce the power consumption of the trench-type MOSFET 10a.

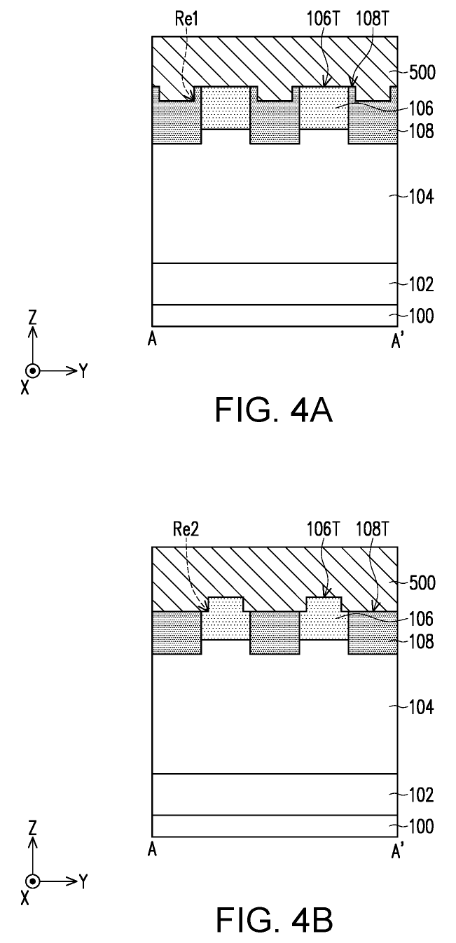

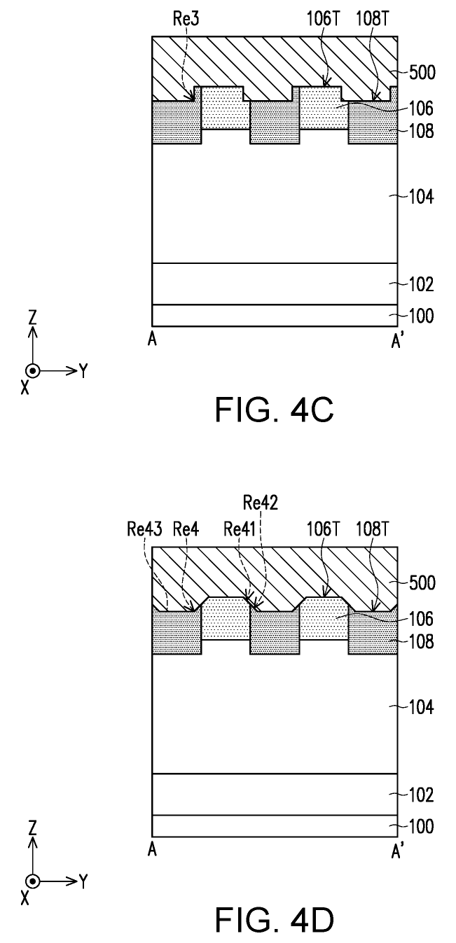

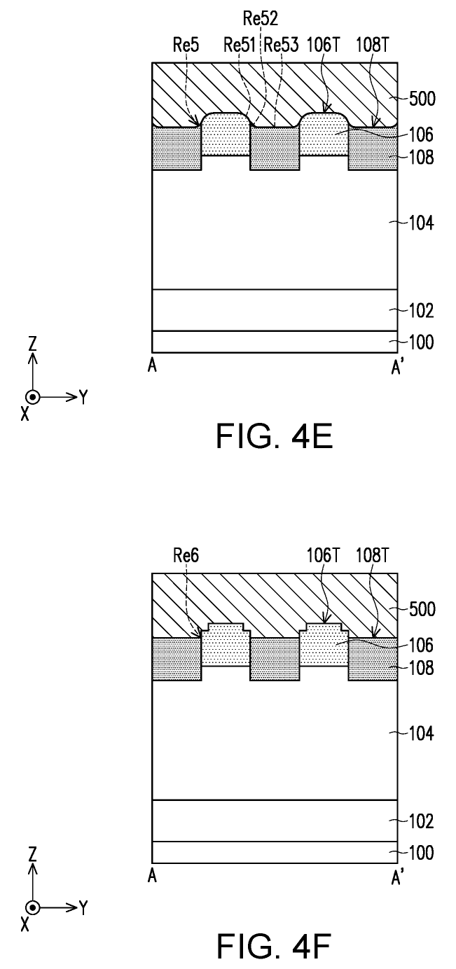

In addition to the morphology of the recess Re shown in FIG. 2A, in other embodiments, the recess Re may have varied morphologies as shown in FIG. 4A to FIG. 4F, but the disclosure is not limited thereto. In this way, it is possible to avoid the strong electric field interaction between the source region 108 and the body contact region 106 due to sharp corner structures, which may cause unpredictable effects on the characteristics of the device.

Please refer to FIG. 4A, the recess Re1 may be formed within the source region 108, such that a part of the surface 108T of the source region 108 may be aligned with the top surface 106T of the body contact region 106. The source electrode 500 may have an extension part corresponding to the morphology of the recess Re1.

Please refer to FIG. 4B, the recess Re2 may be across the source region 108 and a part of the body contact region 106, such that the body contact region 106 may have a cross-sectional shape that is narrower at the top and wider at the bottom. The source electrode 500 may have an extension part corresponding to the morphology of the recess Re2.

Please refer to FIG. 4C, the recess Re3 may be across a part of the source region 108 and a part of the body contact region 106, such that both the source region 108 and the body contact region 106 have cross-sectional shapes that are narrower at the top and wider at the bottom, and both are asymmetrical. The source electrode 500 may have an extension part corresponding to the morphology of the recess Re3.

Please refer to FIG. 4D, the sidewall of the recess Re4 is tapered. Specifically, the dimension of the recess Re4 may be gradually smaller from the top side towards the bottom side (opposite to the direction Z), and has an inclined contour. The upper sidewall Re41 and the lower sidewall Re42 of the recess Re4 each have different conductive types, and the conductive type of the lower sidewall Re42 of the recess Re4 is the same as that of the bottom Re43 of the recess Re4. The source electrode 500 may have an extension part corresponding to the morphology of the recess Re4.

Please refer to FIG. 4E, preferably, the sidewall of the recess Re5 is also tapered. Specifically, the dimension of the recess Re5 may be gradually smaller from the top side towards the bottom side (opposite to the direction Z), and has a smooth contour. Therefore, in this embodiment, the top surface 106T of the body contact region 106 includes a convex surface, and the top surface 108T of the source region 108 includes a concave surface. The upper sidewall Re51 and the lower sidewall Re52 of the recess Re5 each have different conductive types, and the conductive type of the lower sidewall Re52 of the recess Re5 is the same as that of the bottom Re53 of the recess Re5. The source electrode 500 may have an extension part corresponding to the morphology of the recess Re5.

Please refer to FIG. 4F, the sidewall of the recess Re6 is stepped. The stepped contour may expose the body contact region 106. Therefore, in this embodiment, the body contact region 106 may have a cross-sectional shape that is narrower at the top and wider at the bottom. The source electrode 500 may have an extension part corresponding to the morphology of the recess Re6.

In some embodiments, the substrate 100 may further include a drift region 102. The body region 104 may be located between the drift region 102 and the source region 108 or the body contact region 106.

The buried gate structure 200 is formed in the body region 104 and is located at one side of the body contact region 106 and the source region 108. In other words, the body contact region 106 and the source region 108 are alternately arranged at one side of the buried gate structure 200. In this embodiment, the buried gate structure 200 is formed in the gate trench GT located in the body region 104 and the drift region 102, and includes a gate insulating layer 202, a buried gate electrode 204, and an insulating cap layer 206. In this embodiment, the surface 108T of the source region 108 at the bottom of the recess Re is not lower than the top surface 206T of the insulating cap layer 206.

Moreover, the trench-type MOSFET 10a of this embodiment may further include the isolating structure 400 as shown in FIG. 1 and the source electrode 500 as shown in any of FIG. 2B or FIG. 4A to FIG. 4F, but the disclosure is not limited thereto.

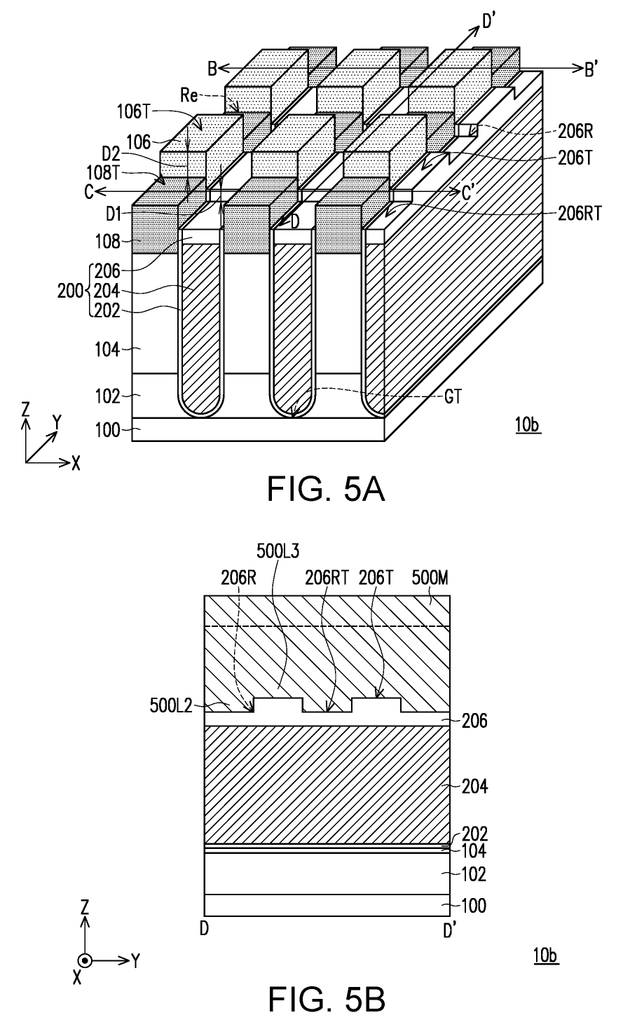

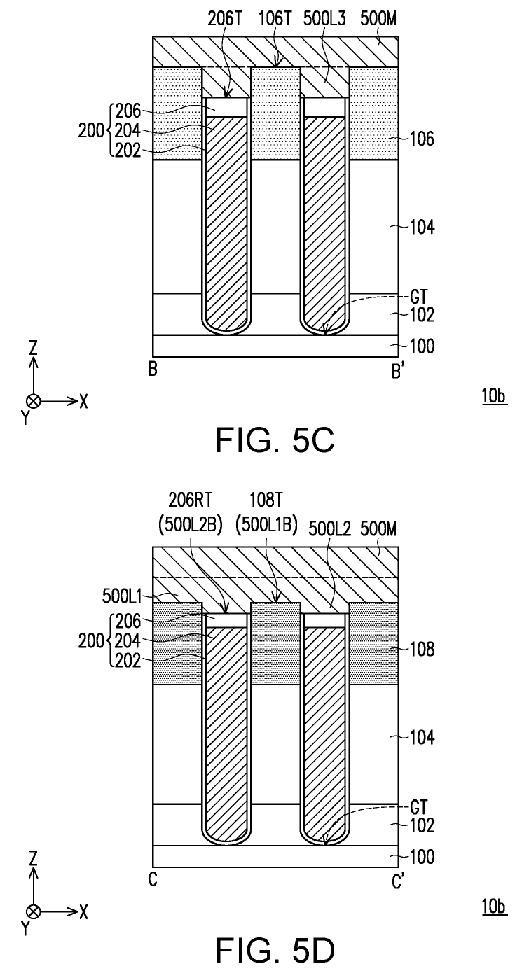

In the following, FIG. 5A to FIG. 5D are adopted to explain the trench-type MOSFET 10b in another embodiment of this disclosure. It should be noted that the embodiments in FIG. 5A to FIG. 5D may each adopt the reference numerals and partial content from the embodiments in FIG. 2A to FIG. 2D, wherein the same or similar reference numerals are used to represent the same or similar components, and explanations of identical technical content are omitted.

Please refer to FIG. 5A to FIG. 5B, in the trench-type MOSFET 10b of this embodiment, the insulating cap layer 206 has a recessed part 206R between multiple source regions 108 at both sides of the buried gate structure 200. The top surface 206RT of the recessed part 206R is lower than the top surface 206T of the insulating cap layer 206 between multiple body contact regions 106 at both sides of the buried gate structure 200.

Please refer to FIG. 5A, in this embodiment, the insulating cap layer 206 has multiple recessed parts 206R arranged along the extension direction (direction Y) of the buried gate structure 200, and the multiple recessed parts 206R have the same period and phase as the multiple recesses Re.

Please refer to FIG. 5A, in this embodiment, the depth D1 of the recessed part 206R is less than the depth D2 of the recess Re.

Please refer to FIG. 5A and FIG. 5D, in this embodiment, the surface 206T of the insulating cap layer 206 between multiple source regions 108 at both sides of the buried gate structure 200 is lower than the surface 108T of the source region 108 at the bottom of the recess Re.

In detail, in the manufacturing method of the trench-type MOSFET 10b of this embodiment, please refer to FIG. 1, the through holes TV of the implantation blocking layer PL also simultaneously expose a part of the insulating cap layer 206. In other words, each of the through holes TV extends in a direction (direction X) perpendicular to the extension direction (direction Y) of the buried gate structure 200. As a result, the etching process that forms the recess Re will also remove a part of the insulating cap layer 206 exposed by the through holes TV. Since the insulating cap layer 206 has a higher etching rate relative to the source region 108, the amount of the removed insulating cap layer 206 will be greater than the amount of the removed source region 108. Based on this, in this embodiment, the top surface 108T of the source region 108 may be higher than the top surface 206T of the insulating cap layer 206. Moreover, as shown in FIG. 5A and FIG. 5B, the top surface 206T of the insulating cap layer 206 between the body contact regions 106 may be higher than the top surface 206RT of the insulating cap layer 206 between the source regions 108. In other words, the top surface of the insulating cap layer 206 of each buried gate structure 200 is an uneven surface.

Moreover, as shown in FIG. 5B, the source electrode 500 may be electrically isolated from the gate electrode 202 through the insulating cap layer 206.

Please refer to FIG. 5B to FIG. 5D, in this embodiment, the source electrode 500 may include a base part 500M, a first extension part 500L1, a second extension part 500L2, and a third extension part 500L3.

The base part 500M is, for example, disposed above the source region 108 and the body contact region 106, and for example, covers the source region 108 and the body contact region 106. As shown in FIG. 5C, in some embodiments, the base part 500M contacts the body contact region 106, but this disclosure is not limited thereto.

The first extension part 500L1 is, for example, filled into the recess Re, so that the bottom surface 500L1B of the first extension part 500L1 is lower than the top surface 106T of the body contact region 106. From another perspective, the first extension part 500L1 is located between adjacent body contact regions 106 in the direction Y.

The second extension part 500L2 is, for example, located on the buried gate structure 200 and adjacent to the first extension part 500L1 in the direction X. Based on this, in this embodiment, the bottom surface 500L2B of the second extension part 500L2 is lower than the bottom surface 500L1B of the first extension part 500L1. From another perspective, the second extension part 500L2 is located between adjacent source regions 108 in the direction X.

The third extension part 500L3 is, for example, located on the buried gate structure 200 and adjacent to the second extension part 500L2 in the direction Y. From another perspective, the third extension part 500L3 is located between adjacent body contact regions 106 in the direction X.

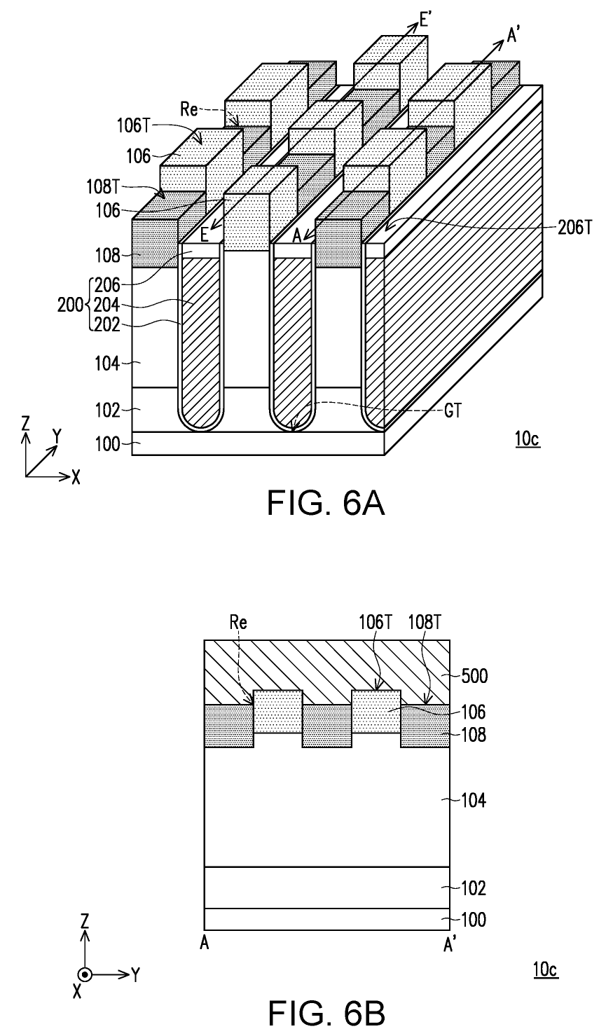

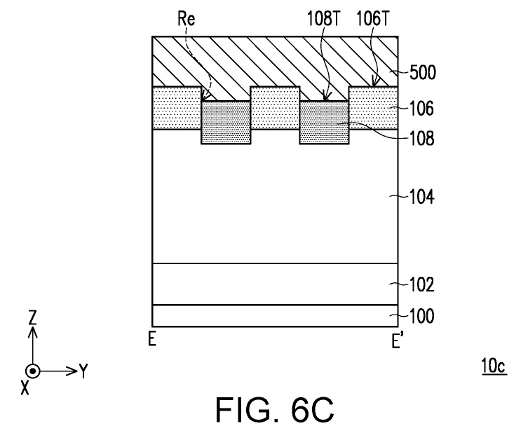

In the following, FIG. 6A to FIG. 6C are adopted to explain the trench-type MOSFET 10c in yet another embodiment of this disclosure. It should be noted that the embodiments in FIG. 6A to FIG. 6C may each adopt the reference numerals and partial content of the embodiments in FIG. 2A to FIG. 2D, where the same or similar reference numerals are used to represent the same or similar components, and explanations of identical technical content are omitted.

Please refer to FIG. 6A to FIG. 6C, in the trench-type MOSFET 10c of this embodiment, the substrate 100 has multiple recesses Re located at a first side of the buried gate structure 200 and a body contact region 106 located at a second side of the buried gate structure 200, wherein the multiple recesses Re and the body contact region 106 are alternately arranged along a direction (direction X) perpendicular to the extension direction (direction Y) of the buried gate structure 200.

In summary, in the manufacturing method of the trench-type MOSFET provided by this disclosure, by forming through holes in the implantation blocking layer, the etching process for removing the hard mask layer disposed on the implantation blocking layer may also remove the partial source region exposed by the through holes, thereby forming recesses and causing the surface of the source region at the bottom of the recesses to be lower than the top surface of the body contact region. Thereby, the trench-type MOSFET provided by this disclosure may have a relatively low on-resistance, which may reduce the power consumption of the trench-type MOSFET. In other words, this disclosure provides a green semiconductor technology.

In addition, in the trench-type MOSFET provided by this disclosure, the width of the source region is not greater than 200 nm, or even less than or equal to 150 nm, therefore this design may be applied to achieve miniaturization of the trench-type MOSFET.

What is claimed is:

1. A trench-type MOSFET, comprising:
a substrate, comprising a body region, a body contact region formed on the body region, and a source region adjacent to the body contact region and formed on the body region, wherein a conductivity type of the source region is different from a conductivity type of the body contact region; and
a buried gate structure, formed in the body region and at a side of the body contact region and the source region,
wherein the substrate has a recess formed on the source region, such that a surface of the source region located at a bottom of the recess is lower than a top surface of the body contact region.

2. The trench-type MOSFET according to claim 1, wherein the source region comprises N-type dopants, and the body contact region comprises P-type dopants.

3. The trench-type MOSFET according to claim 1, further comprising:
a source electrode, covering the source region and the body contact region, and comprising an extension part filled in the recess, so that a bottom surface of the extension part is lower than the top surface of the body contact region,
wherein the substrate further comprises a drift region, and the body region is located between the drift region and the source region or the body contact region.

4. The trench-type MOSFET according to claim 3, wherein the buried gate structure is formed in a gate trench in the body region and the drift region, and comprises:
a gate insulating layer, formed on a surface of the gate trench;
a buried gate electrode, formed on the gate insulating layer; and
an insulating cap layer, formed on the buried gate electrode, wherein the surface of the source region at the bottom of the recess is at a same level as or higher than a top surface of the insulating cap layer.

5. The trench-type MOSFET according to claim 4, wherein the gate trench has an aspect ratio equal to or greater than 2.5, the buried gate electrode comprises a conformal gate layer without voids and a gate filling layer with a void, and the void is at least 10 nm away from the gate insulating layer.

6. The trench-type MOSFET according to claim 4, wherein the insulating cap layer has a recessed part located between the source regions at both sides of the buried gate structure, so that a top surface of the recessed part is lower than the top surface of the insulating cap layer located between the body contact regions at both sides of the buried gate structure.

7. The trench-type MOSFET according to claim 6, wherein the insulating cap layer has the recessed parts arranged along an extension direction of the buried gate structure, and the recessed parts have a same period and phase as the recesses.

8. The trench-type MOSFET according to claim 6, wherein a depth of the recessed part is smaller than a depth of the recess.

9. The trench-type MOSFET according to claim 1, further comprising a source electrode comprising:
a base part covering the source region and the body contact region;
a first extension part filled in the recess, so that a bottom surface of the first extension part is lower than the top surface of the body contact region; and
a second extension part on the buried gate structure and adjacent to the first extension part, wherein a bottom surface of the second extension part is lower than the bottom surface of the first extension part.

10. The trench-type MOSFET according to claim 1, wherein the recess is inside the source region.

11. The trench-type MOSFET according to claim 1, wherein the recess is across a part of the source region and a part of the body contact region.

12. The trench-type MOSFET according to claim 1, wherein an upper sidewall of the recess and a lower sidewall of the recess have different conductivity types, and the lower sidewall of the recess and the bottom of the recess have a same conductivity type.

13. The trench-type MOSFET according to claim 1, wherein a sidewall of the recess is tapered.

14. The trench-type MOSFET according to claim 1, wherein the top surface of the body contact region comprises a convex surface, and the surface of the source region comprises a concave surface.

15. The trench-type MOSFET according to claim 1, wherein a sidewall of the recess is stepped.

16. The trench-type MOSFET according to claim 1, wherein the substrate has a plurality of the recesses at a first side of the buried gate structure and the body contact regions at a second side of the buried gate structure, the plurality of the recesses and the body contact regions are alternately arranged in a direction perpendicular to an extension direction of the buried gate structure.

17. The trench-type MOSFET according to claim 1, wherein a width of the source region is equal to or lower than 200 nm.

18. The trench-type MOSFET according to claim 1, wherein a width of the source region is equal to or lower than 150 nm.

19. A manufacturing method of a trench-type MOSFET, comprising:
forming a body region in a substrate;
forming a body contact region in the body region;
forming a source region adjacent to the body contact region and on the body region, wherein a conductivity type of the source region is different from a conductivity type of the body contact region;
forming a recess on the source region, such that a surface of the source region located at a bottom of the recess is lower than a top surface of the body contact region; and
forming a buried gate structure in the body region and at a side of the body contact region and the source region.

20. The manufacturing method of the trench-type MOSFET according to claim 19, wherein the source region comprises N-type dopants, and the body contact region comprises P-type dopants.

21. The manufacturing method of the trench-type MOSFET according to claim 19, wherein forming the source region comprises:
forming an implantation blocking layer, a hard mask layer and a patterned photoresist layer in sequence on the body region, wherein a thickness of the implantation blocking layer is greater than a thickness of the patterned photoresist layer;
forming a through hole in the implantation blocking layer to expose a surface of the body region;
performing an ion implantation on the exposed surface of the body region to form the source region;
performing an etch process to remove the hard mask layer and form the recess; and
removing the implantation blocking layer.

22. The manufacturing method of the trench-type MOSFET according to claim 21, wherein forming the buried gate structure comprises:
forming a gate trench in the body region;
forming a gate insulating layer on a surface of the gate trench;
forming a buried gate electrode on the gate insulating layer; and
forming an insulating cap layer on the buried gate electrode,
wherein the surface of the source region at the bottom of the recess is at a same level as or higher than a top surface of the insulating cap layer.

23. The manufacturing method of the trench-type MOSFET according to claim 22, wherein during the etch process, the insulating cap layer is also partially removed.

24. The manufacturing method of the trench-type MOSFET according to claim 21, wherein the etch process is a dry etch process using a fluoride ion plasma.

25. The manufacturing method of the trench-type MOSFET according to claim 21, wherein the through hole has an aspect ratio greater than or equal to 7.

26. The manufacturing method of the trench-type MOSFET according to claim 19, wherein forming the buried gate structure comprises:
forming a gate trench in the body region;
forming a gate insulating layer on a surface of the gate trench;
forming a buried gate electrode on the gate insulating layer; and
forming an insulating cap layer on the buried gate electrode,
wherein the surface of the source region at the bottom of the recess is at a same level as or higher than a top surface of the insulating cap layer.

27. The manufacturing method of the trench-type MOSFET according to claim 26, wherein the gate trench has an aspect ratio equal to or greater than 2.5, the buried gate electrode comprises a conformal gate layer without voids and a gate filling layer with a void, and the void is at least 10 nm away from the gate insulating layer.
